(19) United States
(12) Patent Application Publication
(10) Pub. No.: US 2004/0091618 A1
(43) Pub. Date: May 13, 2004

(54) Photoresist depositon apparatus and method for forming photoresist film using the same

(76) Inventors: Han-Su Park, Suwon-city (KR); Young-Jong Kwon, Suwon-city (KR)

Correspondence Address: ROTHWELL, FIGG, ERNST & MANBECK, P.C., 1425 K STREET, N.W., SUITE 800, WASHINGTON, DC, 20005, US

(21) Appl. No.: 10/290,270

(22) Filed: Nov. 8, 2002

(51) Int. Cl. C23C 16/00

(52) U.S. Cl. 427/248.1; 118/715

(57) ABSTRACT

A photoresist deposition apparatus and a method for forming a photoresist film using the apparatus are provided. The photoresist deposition apparatus includes a vacuum chamber including a substrate support on which a substrate is loaded, a photoresist storage tank connected to the vacuum chamber, and a piezoelectric device connected to the photoresist storage tank, which vaporizes a liquid photoresist supplied into the photoresist storage tank into a fumed photoresist in order to supply the fumed photoresist into the vacuum chamber. Since the liquid photoresist is vaporized in the photoresist storage tank, and the fumed photoresist is deposited into the photoresist film in the vacuum chamber under a reduced atmospheric pressure, uniformity in the thickness of the resulting photoresist film can be greatly improved. Since there is no need to rotate the substrate at a high speed, damage to the substrate can be prevented. In addition, there is no need for an additional process for removing an unnecessary photoresist from an edge of the substrate since the photoresist deposition apparatus uses an edge cover during deposition of the photoresist, thereby improving the manufacturing yield and lowering the manufacturing cost.

### BACKGROUND OF THE INVENTION

1. Field of the Invention

The present invention relates to a photoresist deposition apparatus and a method for forming a photoresist film using the apparatus, and more particularly, to an apparatus for depositing a photoresist film on a semiconductor wafer or glass substrate, and a method for forming a photoresist film using the apparatus.

2. Description of the Related Art

In general, it is required to form a predetermined material pattern on a semiconductor wafer or glass substrate in the manufacture of integrated circuit semiconductor devices, liquid crystal displays, plasma displays, etc.

The formation of the predetermined material pattern involves coating a photoresist on a material layer deposited on the semiconductor wafer or glass substrate, forming a photoresist pattern through exposure, and etching the material layer into the predetermined material pattern using the photoresist pattern as an etching mask. In coating the photoresist on the material layer, a photoresist coating apparatus is used. The photoresist coating apparatus will be described in detail with reference to FIG. 1.

FIG. 1 shows a conventional photoresist coating apparatus. Referring to FIG. 1, the conventional photoresist coating apparatus includes in a bath 1 a vacuum chuck 14 which holds a substrate 13, for example, a semiconductor wafer or glass substrate, a motor 19 which is connected to the vacuum chuck 15 via an arm 17 and rotates the substrate 13, and a photoresist nozzle 23 which is disposed above the substrate 13 and dispenses a photoresist 21 onto the substrate 13. The conventional photoresist coating apparatus coats a surface of the substrate 13 with the photoresist 21 using a spin coating method, in which while the substrate 13 loaded on the vacuum chuck 15 is rotated at a constant speed by the motor 19 and the arm 17, a large amount of photoresist 21 is applied to the surface of the substrate 13 and is spread over the substrate 13 due to a centrifugal force in order to form a photoresist film.

Since the conventional photoresist coating apparatus uses the spin coating method so as to deposit the photoresist, the resulting photoresist film on the substrate is poor in thickness uniformity. In addition, the high-speed rotation of the substrate during deposition of the photoresist may damage the substrate, especially a large substrate, and may further reduce uniformity in the thickness of the photoresist film.

The spin coating method used in the conventional photoresist coating apparatus needs a large amount of photoresist and an additional process for removing an unnecessary photoresist from the edge of the substrate after the photoresist has been coated.

### SUMMARY OF THE INVENTION

Accordingly, the invention provides a photoresist deposition apparatus for forming a photoresist film having a uniform thickness without damaging a substrate and without a need for a large amount of photoresist and an additional process for removing an unnecessary photoresist from an edge of the substrate, which are encountered when a spin coating method is applied as in conventional photoresist coating apparatuses.

The invention also provides a method for forming a photoresist film using the photoresist deposition apparatus.

In an aspect, the invention provides a photoresist deposition apparatus comprising: a vacuum chamber including a substrate support on which a substrate is loaded; a photoresist storage tank connected to the vacuum chamber; and a piezoelectric device connected to the photoresist storage tank, which vaporizes a liquid photoresist supplied into the photoresist storage tank into a fumed photoresist in order to supply the fumed photoresist into the vacuum chamber.

The photoresist deposition apparatus according to the present invention may further comprise a photoresist supply conduit which is installed through an upper body of the vacuum chamber and via which the fumed photoresist is supplied into the vacuum chamber. The photoresist deposition apparatus according to the present invention may further comprise an edge cover which covers an edge of the substrate loaded on the substrate support in order to prevent the photoresist film from being formed on the edge of the substrate.

The photoresist deposition apparatus according to the present invention may further comprise a rectifying plate over the substrate in the vacuum chamber, which rectifies the fumed photoresist such that the fumed photoresist is spread over the substrate. The photoresist deposition apparatus according to the present invention may further comprise a liquid photoresist pump connected to a liquid photoresist container, which sucks in the liquid photoresist from the liquid photoresist container and pumps the sucked liquid photoresist into the photoresist storage tank.

The photoresist deposition apparatus according to the present invention may further comprise a pump connected to the photoresist storage tank, which controls the inner pressure of the photoresist storage tank. In the photoresist deposition apparatus according to the present invention, the piezoelectric device may be disposed contacting an outer bottom of the photoresist storage tank or within the photoresist storage tank.

In another aspect, the invention provides a method for forming a photoresist film, the method comprising: loading a substrate onto a substrate support placed in a vacuum chamber; transferring a liquid photoresist in a liquid photoresist container into a photoresist storage tank connected to the vacuum chamber; and a piezoelectric device vaporizing the liquid photoresist supplied into the photoresist storage tank into a fumed photoresist so that the fumed photoresist is deposited into the photoresist film on the substrate.

In the photoresist film formation method according to the present invention, the supplying the liquid photoresist into the photoresist storage tank and the vaporizing the liquid photoresist into the fumed photoresist can be simultaneously performed. The photoresist film formation method according to the present invention may further comprise heating the substrate after the photoresist film has been formed in order to remove a solvent from the photoresist film.

When the photoresist film is formed, the inner pressure of the vacuum chamber is controlled to a reduced atmospheric pressure, for example, in the range of 500-10⁻ⁿ Torr, where n is an integer. The piezoelectric device vaporizing the liquid photoresist into the fumed photoresist can be disposed contacting an outer bottom of the photoresist storage tank or within the photoresist storage tank.

As described above, in the method for forming a photoresist film using the photoresist deposition apparatus according to the present invention, the liquid photoresist is vaporized into the fumed photoresist within the photoresist storage tank and is then deposited on the substrate in the vacuum chamber under a reduced atmospheric pressure, so that uniformity in the thickness of the photoresist film can be greatly improved.

### BRIEF DESCRIPTION OF THE DRAWINGS

The above features and advantages of the present invention will become more apparent by describing in detail exemplary embodiments thereof with reference to the attached drawings in which:

FIG. 1 shows a conventional photoresist coating apparatus;

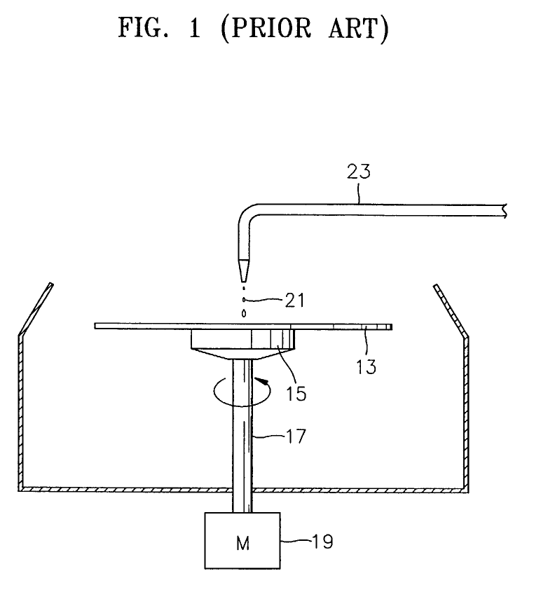

FIG. 2 shows a photoresist deposition apparatus according to an embodiment of the present invention; and

FIG. 3 is a flowchart of a method for forming a photoresist film using the photoresist deposition apparatus of FIG. 2, according to the present invention.

### DETAILED DESCRIPTION OF THE INVENTION

The present invention will be described more fully with reference to the accompanying drawings, in which exemplary embodiments of the invention are shown. This invention may, however, be embodied in many different forms and should not be constructed as being limited to the embodiments set forth herein; rather, these embodiments are provided so that this disclosure will be thorough and complete, and will fully convey the concept of the invention to those skilled in the art.

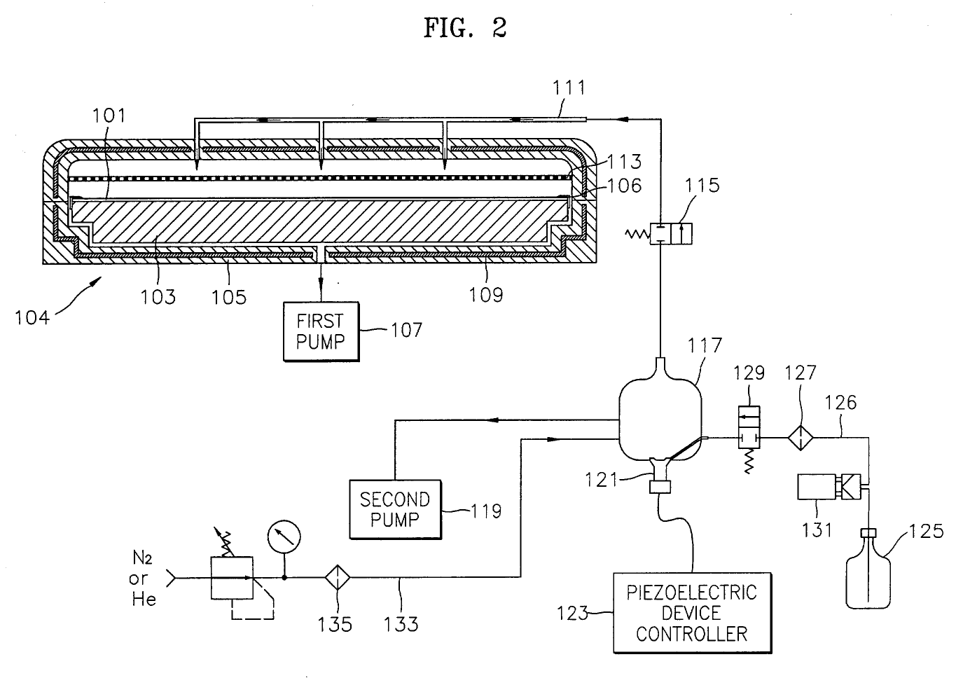

The structure of a photoresist deposition apparatus according to an embodiment of the present invention is shown in FIG. 2. Referring to FIG. 2, the photoresist deposition apparatus according to the present invention includes a vacuum chamber 104 in which a substrate support 103 is placed. The inner space of the vacuum chamber 104 is defined by a body 105. An edge cover 106 which covers the edge of a substrate 101 loaded on the substrate support 103 such that no photoresist film is formed on the edge of the substrate 101 is disposed. A first pump 107 for controlling the pressure of the vacuum chamber 104 is connected to the vacuum chamber 104. A heater 109 for controlling the temperature of the vacuum chamber 104 is disposed in the body 105 of the vacuum chamber 104.

Through an upper body of the vacuum chamber 104 a photoresist supply conduit 111 through which a fumed photoresist is supplied into the vacuum chamber 104 is formed. A rectifying plate 113 which rectifies the fumed photoresist introduced into the vacuum chamber 104 through the photoresist supply conduit 111 such that the fumed photoresist is spread over the substrate 101 is disposed above the substrate 101. The fumed photoresist passed through the rectifying plate 113 is deposited on the substrate 101 and then exhausted out of the vacuum chamber 104 through the space between the substrate support 103 and a lower body of the vacuum chamber 104. A unit that changes a liquid photoresist into the fumed photoresist will be described below.

A mass flow controller (MFC) 115 and a photoresist storage tank 117 are connected in series to the photoresist supply conduit 111. In other worlds, the photoresist storage tank 117 is connected to the vacuum chamber 104 via the photoresist supply conduit 111. The photoresist storage tank 117 is connected to a second pump 119 for controlling the inner pressure of the photoresist storage tank 117. A piezoelectric device 121 which vaporizes the liquid photoresist into the fumed photoresist in the photoresist storage tank 117 and supplies the fumed photoresist into the photoresist chamber 104 is connected to the photoresist storage tank 117. The piezoelectric device 121 can be, for example, a vibrator. Although in FIG. 2 the piezoelectric device 121 is illustrated as contacting the outer bottom of the photoresist storage tank 117, the piezoelectric device 121 can be installed within the photoresist storage tank 117. The piezoelectric device 121 vaporizes the liquid photoresist in the photoresist storage tank 117 by transferring energy in contact with a piezoelectric device controller 123. The amount by which the liquid photoresist is vaporized can be controlled by the inner pressure of the photoresist storage tank 117, the controlling capability of the piezoelectric device controller 123, etc.

The photoresist storage tank 117 is connected to a liquid photoresist container 125. A liquid photoresist pump 131 is connected to the liquid photoresist container 125. The liquid photoresist pump 131 sucks in the liquid photoresist from the liquid photoresist container 125 and pump the liquid photoresist into the photoresist storage tank 117 via a first filter 127 and an inlet valve 129, which are connected through a liquid photoresist supply conduit 126 to the liquid photoresist pump 131. The first filter 124 removes impurities from the liquid photoresist.

The photoresist storage tank 117 is connected to an inert gas pipeline 133 via which an inert gas, such as nitrogen or helium, is supplied into the photoresist storage tank 117. The inner pressure of the photoresist storage tank 117 and the inner pressure of the vacuum chamber 104, into which the inert gas can be supplied via the photoresist supply conduit 111, can be controlled using the inert gas. A second filter 135 for removing impurities is disposed in the inert gas pipeline 133.

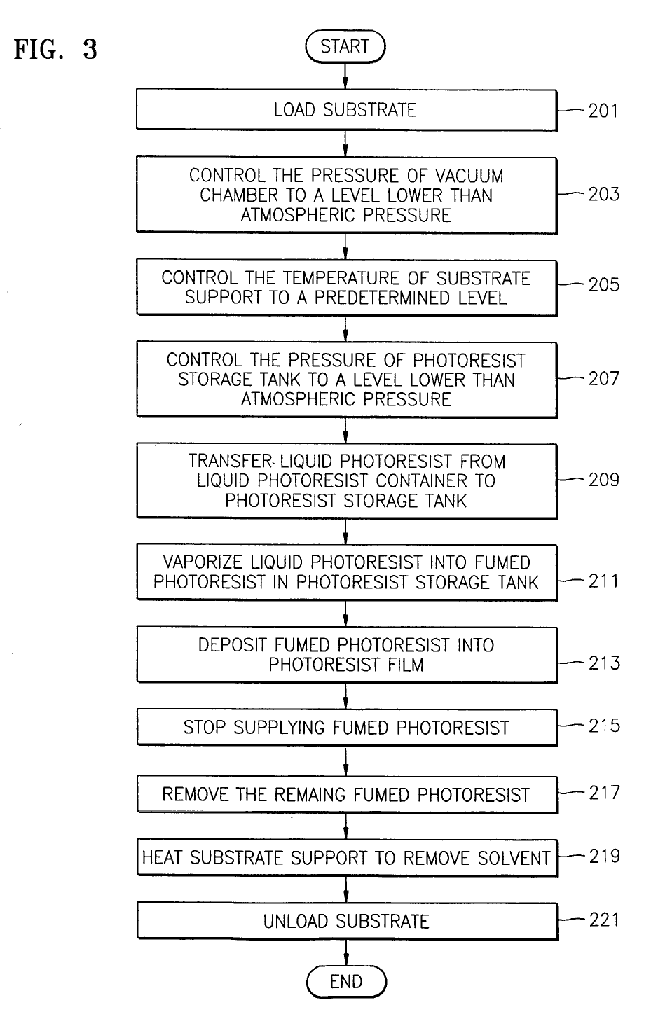

Hereinafter, a method for forming a photoresist film on a substrate using the photoresist deposition apparatus as described above, according to the present invention, will be described with reference to FIGS. 2 and 3.

FIG. 3 is a flowchart of a method for forming a photoresist film using the photoresist deposition apparatus of FIG. 2, according to an embodiment of the present invention.

In particular, the substrate 101 is loaded onto the substrate support 103 in the vacuum chamber 104 in step 201. Next, the first pump 107 connected to the vacuum chamber 104 is operated in order to control the inner pressure of the vacuum chamber 104 to a level lower than atmospheric pressure, for example, in the range of 500-10⁻ⁿ Torr, where n is an integer, in step 203. The temperature of the substrate support 103 is controlled to a predetermined level, for example, 25-200° C., using the heater 109 in step 205.

Next, the inner pressure of the photoresist storage tank 117 is controlled to a level lower than atmospheric pressure, for example, in the range of 100-200 Torr, using the second pump 119 in step 207. The liquid photoresist in the liquid photoresist container 125 is supplied into the photoresist storage tank 117 via the first filter 127 and the inlet valve 129 using the liquid photoresist pump 131 in step 209. The inlet valve 129 is opened to allow the liquid photoresist to enter the photoresist storage tank 117 or is closed to suspend supplying the liquid photoresist into the photoresist storage tank 117 by on-off control.

Next, the liquid photoresist supplied into the photoresist storage tank 117 is converted into a fumed photoresist using the piezoelectric device 212 and the piezoelectric device controller 123 in step 211. As described above, the piezoelectric device 121 is disposed contacting the outer bottom of the photoresist storage tank 117 or within the photoresist storage tank 117 and vaporizes the liquid photoresist into the fumed photoresist. The fumed photoresist is primarily stored in the photoresist storage tank 117. Although in the embodiment supplying the liquid photoresist into the photoresist storage tank 117 (step 209) and vaporizing the liquid photoresist in the photoresist storage tank 117 into the fumed photoresist (step 211) are described as separate steps, the liquid photoresist can be vaporized into the fumed photoresist while being supplied into the photoresist storage tank 117.

Next, the fumed photoresist in the photoresist storage tank 117 is supplied into the vacuum chamber 104 via the MFC 115 and the photoresist supply conduit 111 at a predetermined flow rate for a predetermined time period in order to form a photoresist film on the substrate 101 loaded on the wafer support 103 in step 213. When a photoresist film is formed on the substrate 101 in the vacuum chamber 104 under a reduced atmospheric pressure using the fumed photoresist as described above, uniformity in the thickness of the photoresist film can be markedly improved.

Next, supplying the fumed photoresist is cut off in step 215. In other words, the inlet valve 129 is closed in order to suspend supplying the liquid photoresist into the photoresist storage tank 117. Also, the operation of the piezoelectric device 121 and the piezoelectric device controller 123 are suspended to stop vaporizing the liquid photoresist into the fumed photoresist in the photoresist storage tank 117.

Next, an inert gas, such as nitrogen or halogen, is supplied into the photoresist storage tank 117 and the vacuum chamber 104 via the inert gas pipeline 133 in order to purge the remaining fumed photoresist from the photoresist storage tank 117 and the vacuum chamber 104 in step 217.

Next, the substrate support 103 in the vacuum chamber 104 is heated by the heater 109 in order to vaporize and remove a solvent from the photoresist film in step 219. The photoresist deposition apparatus according to the present invention can simultaneously deposit a photoresist film and remove the solvent from the photoresist film, which are separately performed in different units in the prior art. As a result, the amount of particles in the photoresist film and the number of processing steps in the manufacture of semiconductor devices can be reduced, thereby reducing the manufacturing cost and improving productivity.

Next, the inner pressure of the vacuum chamber 104 is returned to atmospheric pressure by supplying the inert gas into the vacuum chamber 104 via the inert gas supply pipeline 133, and the substrate 101 on which the photoresist film has been formed is unloaded from the vacuum chamber 104. As a result, one cycle of forming the photoresist film on the substrate 101 is complete.

As described above, the photoresist deposition apparatus according to the present invention deposits a fumed photoresist rather than a liquid photoresist on the vacuum chamber under a reduced atmospheric pressure, so that the thickness uniformity of the resulting photoresist film on the substrate can be greatly improved. In addition, since there is no need to rotate the substrate at a high speed, damage to the substrate, which occurs in conventional photoresist coating apparatuses, can be prevented, thereby improving the manufacturing yield and lowering the manufacturing cost.

Unlike conventional photoresist coating apparatuses that use a spin coating technique, when the photoresist deposition apparatus according to the present invention is used, the amount of photoresist used can be reduced, and no additional process for removing an unnecessary photoresist from the edge of the substrate is required, thereby improving productivity. In addition, the solvent in the photoresist film can be removed immediately after deposition of the photoresist film by heating the substrate.

What is claimed is:

1. A photoresist deposition apparatus comprising:
a vacuum chamber including a substrate support on which a substrate is loaded;
a photoresist storage tank connected to the vacuum chamber; and
a piezoelectric device connected to the photoresist storage tank, which vaporizes a liquid photoresist supplied into the photoresist storage tank into a fumed photoresist in order to supply the fumed photoresist into the vacuum chamber.

2. The photoresist deposition apparatus of claim 1, further comprising a photoresist supply conduit which is installed through an upper body of the vacuum chamber and via which the fumed photoresist is supplied into the vacuum chamber.

3. The photoresist deposition apparatus of claim 1, further comprising an edge cover which covers an edge of the substrate loaded on the substrate support in order to prevent the photoresist film from being formed on the edge of the substrate.

4. The photoresist deposition apparatus of claim 1, further comprising a rectifying plate over the substrate in the vacuum chamber, which rectifies the fumed photoresist such that the fumed photoresist is spread over the substrate.

5. The photoresist deposition apparatus of claim 1, further comprising a liquid photoresist pump connected to a liquid photoresist container, which sucks in the liquid photoresist from the liquid photoresist container and pumps the sucked liquid photoresist into the photoresist storage tank.

6. The photoresist deposition apparatus of claim 1, further comprising a pump connected to the photoresist storage tank, which controls the inner pressure of the photoresist storage tank.

7. The photoresist deposition apparatus of claim 1, wherein the piezoelectric device is disposed contacting an outer bottom of the photoresist storage tank or within the photoresist storage tank.

8. A method for forming a photoresist film, the method comprising:
loading a substrate onto a substrate support placed in a vacuum chamber;
transferring a liquid photoresist in a liquid photoresist container into a photoresist storage tank connected to the vacuum chamber; and
a piezoelectric device vaporizing the liquid photoresist supplied into the photoresist storage tank into a fumed photoresist so that the fumed photoresist is deposited into the photoresist film on the substrate.

9. The method of claim 8, wherein the supplying the liquid photoresist into the photoresist storage tank and the vaporizing the liquid photoresist into the fumed photoresist are simultaneously performed.

10. The method of claim 8, further comprising heating the substrate after the photoresist film has been formed in order to remove a solvent from the photoresist film.

11. The method of claim 11, wherein the inner pressure of the vacuum chamber is in the range of 500-10₋ₙ Torr, where n is an integer, when the photoresist film is formed.

12. The method of claim 8, wherein the piezoelectric device vaporizing the liquid photoresist into the fumed photoresist is disposed contacting an outer bottom of the photoresist storage tank or within the photoresist storage tank.
